(19) United States
(12) Patent Application Publication
(10) Pub. No.: US 2005/0224663 A1
(43) Pub. Date: Oct. 13, 2005

(54) Modular transformer lead support system

(75) Inventors: Kevin M. Biggie, St. Johnsbury, VT (US); James G. Cross, Waterford, VT (US); Brian A. McFarland, Danville, VT (US)

Correspondence Address: DOWNS RACHLIN MARTIN PLLC, 199 MAIN STREET, P O BOX 190, BURLINGTON, VT, 05402-0190, US

(73) Assignee: EHV-Weidmann Industries, Inc., St. Johnsbury, VT (US)

(21) Appl. No.: 11/101,097

(22) Filed: Apr. 7, 2005

Related U.S. Application Data
(62) Division of application No. 10/068,121, filed on Feb. 5, 2002, now abandoned.
(60) Provisional application No. 60/267,498, filed on Feb. 5, 2001.

(51) Int. Cl. F16L 3/08; H01L 23/28

(52) U.S. Cl. 248/67

(57) ABSTRACT

A modular support system (20) for supporting electrical leads (24) within the tank (28) of a power transformer (22). The support system includes a plurality of standardized frame members (38) and a plurality of standardized lead supports (45). Each standardized frame member has a plurality of apertures (50) spaced from one another along its length. The arrangement of the apertures allows the support system to be configured in any of variety of configurations to suit a particular arrangement of transformer leads. The standardized frame members are connected to one another with connections (56) that each engage corresponding apertures. Similarly, each lead support is connected to one of the standardized frame members with a connection (62) that engages corresponding apertures.

### RELATED APPLICATION DATA

This application claims the benefit of priority of U.S. Provisional Patent Application No. 60/267,498, filed Feb. 5, 2001, entitled “Modular Lead Support Structure for a Transformer.”

### FIELD OF THE INVENTION

The present invention is generally related to the field of supports for electrical conductors. More particularly, the present invention is directed to a modular system for supporting electrical leads of an electrical power transformer.

### BACKGROUND OF THE INVENTION

A typical high-voltage transformer of the type used in the commercial and industrial power generation industries comprises a core and coil (winding) assembly contained within a tank filled with oil. High voltage, low voltage and tap winding current carrying conductors, or leads, extend from the core/coil assembly to the exterior of the through bushings in the wall of the tank. A lead support structure is typically secured to the core/coil assembly inside the tank and secures the leads in place to maintain proper electrical clearance between adjacent leads and between the leads and other components having different electrical potential. A properly-designed lead support structure must be able to resist continuous vibration, shipping forces and short-circuit forces produced during external system faults.

Presently, lead support structures of adequate strength are typically custom-made for each different transformer design (rating, voltage class, impedance, etc.) from solid-cross-section structural members made from solid maple, laminated beech wood or cellulose-based laminated pressboard. For example, conventional members include solid pieces of 2″×3″ or 2″×4″ nominal cross-section lumber or so-called “angle-rail,” which is a laminated pressboard angle that typically has equal legs 6″ wide and ½″ to ⅝″ thick.

Structural members made of solid material are particularly wasteful of material in that their strength/weight ratio is very low. Angle rail structural members have better material utilization, but suffer from high production cost due to the laminated nature of the product and the long cycle time to produce the angle rail. In terms of fabrication, each member of a conventional lead support structure is a unique piece, with holes and other features drilled, milled or cut into the member in such a manner as to facilitate interconnection of a plurality of structural members to form a particular fixed, custom configuration using non-conductive hardware.

As a result of the customized nature of conventional lead support structures and their constituent members, considerable design time is required on the part of transformer manufacturers to prepare fabrication and assembly drawings for these structures. In addition, since every lead support structure is unique, the manufacturing and assembly times are significant and opportunities for error are high.

### SUMMARY OF THE INVENTION

In one aspect, the present invention is directed to a support system for supporting at least one supported item. The support system comprises a plurality of standardized members, each having a first length and plurality of connection receivers spaced from one another in a direction along the first length, connected to one another so as to form a frame generally defining a plane. A plurality of first connectors engages corresponding ones of the plurality of connection receivers so as to secure the plurality of standardized members to one another to form the frame. At least one support, for supporting the at least one supported item, extends in a direction away from the plane of the frame. At least one second connector engages at least one of the plurality of connection receivers and the at least one support to secure the at least one support to the frame.

In another aspect, the present invention is directed to a transformer. The transformer comprises at least a first lead and a lead support system. The lead support system includes at least one elongate frame member having a first longitudinal axis. At least one lead support supports the at least one lead and is movably secured to the at least one elongate frame member so as to be repositionable along the first longitudinal axis.

### BRIEF DESCRIPTION OF THE DRAWINGS

For the purpose of illustrating the invention, the drawings show a form of the invention that is presently preferred. However, it should be understood that the present invention is not limited to the precise arrangements and instrumentalities shown in the drawings, wherein:

FIG. 1 is a perspective view of a modular support system of the present invention;

FIG. 2 is a elevational cross-sectional view of a transformer that includes the modular support system of FIG. 1;

FIG. 3 is an enlarged cross-sectional view of a first connection between a pair of standardized frame members as taken along line 3-3 of FIG. 1;

FIG. 4 is an enlarged cross-sectional view of a second connection between a pair of standardized frame members as taken along line 4-4 of FIG. 1;

FIG. 5 is an enlarged cross-sectional view of a splice as taken along line 5-5 of FIG. 1;

FIG. 6 is an enlarged partial cross-sectional view showing one of the lead supports engaging one of the standardized frame members;

FIG. 7 is an elevational view of an alternative lead support;

FIG. 8 is a perspective view of an alternative embodiment of the modular support system of the present invention that includes tubular standardized frame members;

FIG. 9 is an cross-sectional view of an alternative tubular standardized frame member;

FIG. 10 is a cross-sectional view of an alternative standardized frame member of a modular support system of the present invention; and

FIG. 11 is a plan view of two components of the standardized frame member shown in FIG. 10.

### DETAILED DESCRIPTION OF THE INVENTION

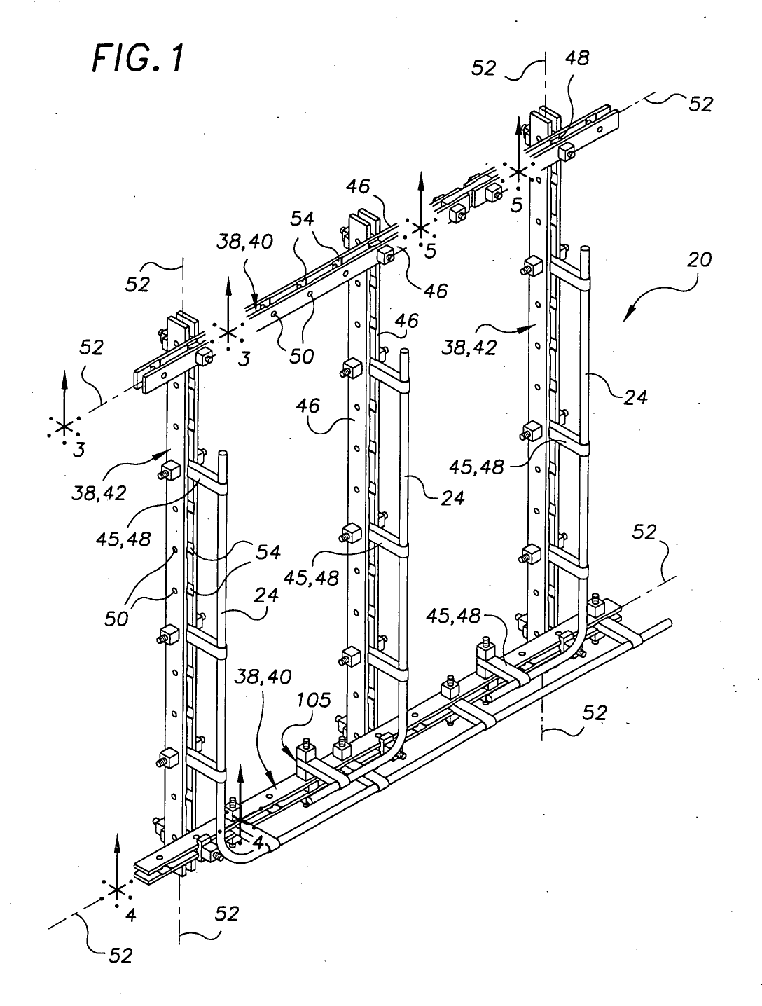

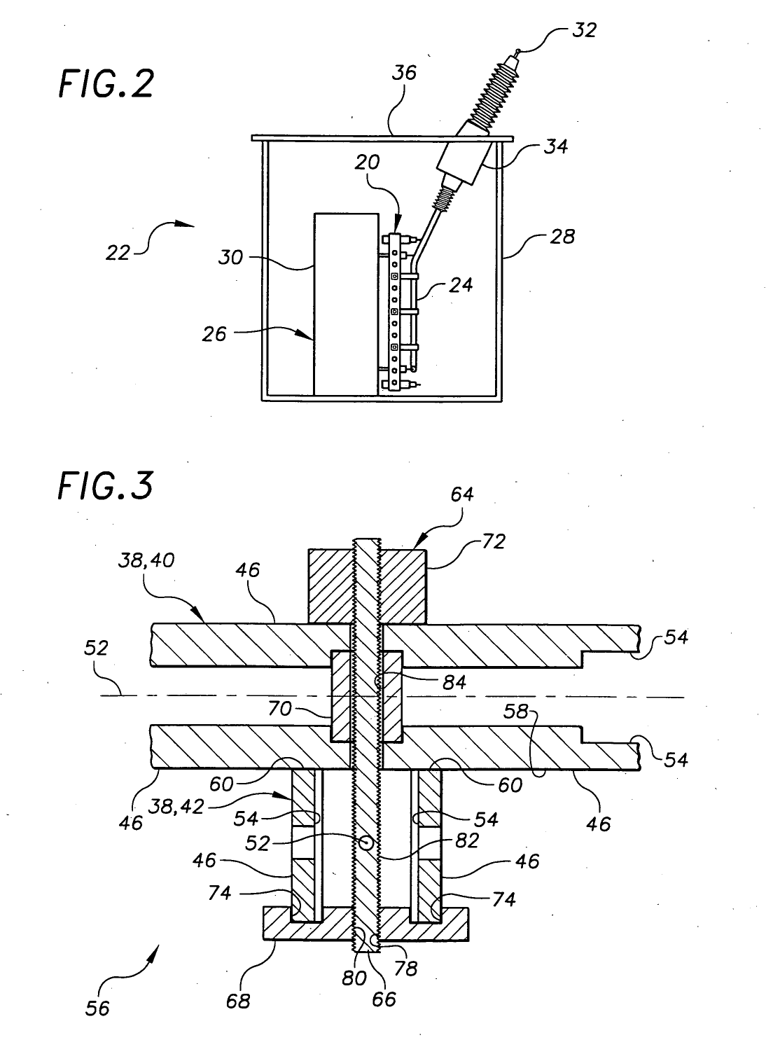

Referring now to the drawings, wherein like numerals indicate like members, FIG. 1 illustrates in accordance with the present invention a modular support system, which is generally denoted by the numeral 20. As shown in FIG. 2, modular support system 20 may be used in conjunction with an electrical power transformer 22 to support one or more electrical conductors, or leads 24, in fixed, spaced relation from one another and/or from other components of the transformer to prevent electrical arcing, short circuiting and other detrimental effects.

Advantageously, modular support system 20 may be assembled using standardized members and connections that allow it to be readily configured and adapted to transformers of different sizes and/or designs. Accordingly, modular support system 20 can significantly reduce costs and opportunities for errors in relation to conventional custom-build lead support structures. Appropriate design of the various members of modular support system 20 themselves offers yet further opportunities for cost-reduction in terms of material content by increasing their strength/weight ratio and thus reducing component weights while maintaining the required strength. As will become readily apparent from the below description of modular support system 20, important improvements of the modular support system of the present invention over conventional transformer lead supports include: significantly higher strength/weight ratios compared to conventional solid structural members; reduced weight; the ability to create complex support systems from a small number of standard structural members; and infinite and/or discretized adjustability of a grid-like support system without additional machining or fabrication.

Although modular support system 20 is shown and described in the context of power transformer 22, those skilled in the art will appreciate that the modular support system of the present invention may be used in other applications. For example, instead of supporting transformer leads 24, modular support system 20 may support other supported items, such as other electrical conductors, e.g., power distribution cable and control wiring, optical cables and fluid piping, among others. In even more general terms, modular support system 20 is suited for use in any applications requiring the support of one or more supported items in fixed relation to one another and/or adjacent structures, if any. As used herein and in the claims appended hereto, the term “supported item” denotes items that are functionally separate from the modular support system 20. That is, a supported item is not a part, or member, of modular support system 20, but rather has its own function distinct from the modular support system. In addition, modular support system 20 is particularly suited for situations wherein it is beneficial to have a support that is readily adaptable into different configurations to suit various configurations and/or arrangement of the supported item(s) supported, among other variables.

As mentioned, FIG. 2 shows modular support system 20 used in conjunction with power transformer 22. Transformer 22 may be of the oil-filled type commonly used in utility power grids and large industrial power supply systems and other applications. Accordingly, transformer 22 may comprise a core/coil assembly 26 located within a tank 28 filled with oil (not shown), such as mineral oil. Depending upon the type of transformer 22, e.g., single phase, two phase or three phase, core/coil assembly 26 may have one or more windings, or coils 30, each having high voltage lead 24 and a low voltage lead (not shown). Each high voltage lead 24 (and low voltage lead) extends from the respective coil 30, through a portion of tank 28, and to a corresponding terminal 32 located outside the tank. Each lead 24 is supported by a bushing 34 that engages a wall 36 of tank 28.

Modular support system 20 supports leads 24 within tank 28 between the core/coil assembly 26 and corresponding bushings 34. Modular support system 20 may be attached to core/coil assembly 26 with mechanical fasteners or other suitable means (not shown), in a manner know in the art. As those skilled in the art will recognize, only several primary components of transformer 22 are shown for the purpose of illustrating the present invention. Other components may include low-voltage terminals, bushings and leads, a control enclosure and corresponding systems, one or more radiators, and a load tap changer, among others.

Referring again to FIG. 1, modular support system 20 may comprise a plurality of standardized frame members 38, such as horizontal frame members 40 and vertical frame members 42, secured to one another to generally form a frame 44. Modular support system 20 may also include a plurality of supports 45 that maintain leads 24 in fixed relation to one another and to frame 44. Horizontal frame members 40 and vertical frame members 42 are preferably, but not necessarily, made using identical components or sub-components as described below. In general, it is desirable to minimize the number of different components, e.g., to increase the simplicity of modular support system 20, minimize cost, and minimize the number of different types of components that must be inventoried.

Modular support system 20 shown is particularly adapted to support three leads 24 of a three-phase transformer 22 in the manner shown. Accordingly, modular support system 20 may include three vertical frame members 42 and two horizontal frame members 40. However, those skilled in the art will readily appreciate that the configuration of frame 44, e.g., the generally rectangular grid shape, the particular number of horizontal frame members 40 and vertical frame members 42 and orientations of the frame members relative to one another, may be any configuration desired that suits a particular application. In addition, it is noted that although modular support system 20 is shown as being in a vertical plane, it may be oriented in any plane. Thus, the terms horizontal and vertical are not limiting and may be suitably replaced with alternative language, such as transverse and longitudinal, appropriate for the orientation under consideration.

Each standardized frame member 38 may include a pair of spaced rails 46. As will become apparent from the discussion below, rails 46 of each standardized frame 38 member may be spaced from one another by any one of a number of different types of spacers 48, depending upon the location and/or function of the spacer. Each rail 46 may include a plurality of connection receivers, such as apertures 50 spaced from one another along the longitudinal axis 52 of each standardized frame member 38. Each aperture 50 may be circular, square, or other shape, depending upon a particular design. Each rail 46 may also optionally include a plurality of grooves 54 extending in a direction perpendicular longitudinal axis 52, e.g., if modular support system 20 is configurable into a rectangular grid pattern or shape, or in a direction oblique with respect to the longitudinal axis, e.g., if the module support system is configurable into a non-rectangular grid pattern or shape.

Rails 46 may be made out of any material such as a cellulose composite, laminated wood, plastic, or metal, among others. For use in conjunction with supporting leads 24 of transformer 22 (FIG. 2), however, rails 46 should be made of a dielectric material to prevent any electrical interaction between the electricity carried by the leads and frame 44. In one embodiment, rails 46 are made of a high density cellulose laminated pressboard, which is a porous material that is impregnatable with the oil used in transformer 22. Impregnating the cellulose pressboard rails 46, or any other members of modular support system 20 made from cellulose pressboard, with oil generally prevents partial discharge from occurring within these members. Partial discharge can occur in materials containing air-filled voids when subjected to relatively intense electrical fields, such as occur inside large commercial transformers. The electrical field can cause arcing across the voids and, consequently, carbonization of the walls of these voids. Long-term exposure to intense electrical fields can cause significant deterioration of materials containing air-filled voids. Of course, other oil impregnatable dielectric materials or non-porous materials may be used in place of the oil impregnatable cellulose pressboard.

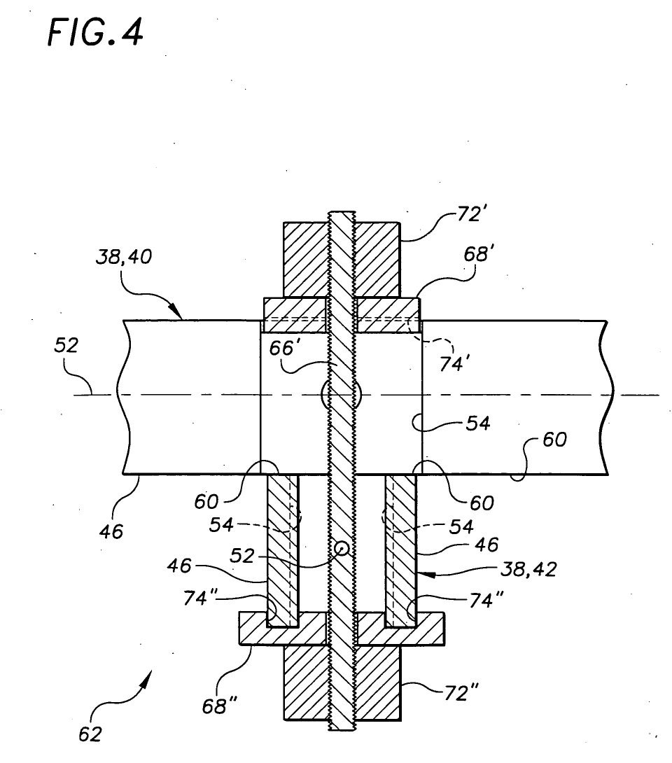

Horizontal frame members 40 may be joined to vertical frame members 42 in any one of a number of connection configurations. For example, FIG. 3 shows a connection 56 wherein the outer face 58 of one rail 46 of horizontal frame member 40 confronts a longitudinal side 60 of each of the two rails of vertical frame member 42. In comparison, FIG. 4 shows a connection 62 wherein longitudinal side 60 of each rail 46 of horizontal frame member 40 confronts longitudinal side 60 of each rail 46 of vertical frame member 42. Another possible connection (not shown) is one in which an outer face 58 of a rail 46 of a horizontal frame member 40 confronts an outer face of a rail of a vertical frame member 42. Of course, depending upon the intended application, horizontal frame member 40 may be located on either side of vertical frame member 42 or vice versa. In addition, a horizontal frame member 40 may be present on each side of a vertical frame member 42, or vice versa, or a vertical frame member may be present between the two rails 46 of a horizontal frame member 40, or vice versa. In the latter case, the thickness of spacers 48 used to space apart rails 46 of horizontal frame member would have to be increased to accommodate the larger spacing between the rails due to the presence of vertical frame member 42 therebetween.

Referring again to FIG. 3, this figure shows connection 56 adapted for discretized adjustability along both horizontal frame member 40 and vertical frame member 42. Accordingly, connection 56 may include a fastening system 64 that may include connection components such as a threaded rod 66, a movable connector 68, a spacer 70 and a nut 72. Those skilled in the art will appreciate that a fastening system 64 may be a type other than a threaded fastening system. For example, fastening system 64 may include a non-threaded rod (not shown), or other elongate member, having a stop at each end. The stop may be made by deforming the end of the member, e.g., a rivet head, bolt head or the like, or may be a component secured to the rod, e.g., a cotter pin, wedge, or press-fit nut, among others. Threaded rod 66 and nut 72 may be made of any suitable material, such as plastic, e.g., Nylon 6/6, wood, cellulose or other composite, or metal, among others. Similarly, spacer 70 and movable connector 68 may be made of any of these materials. However, when used in conjunction with transformer 22 (FIG. 2), these components should be made of a dielectric material to prevent any electrical interaction between the electricity carried by leads and connection 56. As discussed above, such dielectric materials may be oil impregnatable.

In the embodiment shown, movable connector 68 is planar and generally rectangular in shape. However, movable connector 68 may be curved or otherwise non-planar and may be any shape desired. To provide discretized adjustability of horizontal frame member 40 relative to vertical frame member 42, i.e., wherein the horizontal frame member may be located only at positions corresponding to grooves 54 of the vertical frame member, movable connector 68 may include a pair of spaced channels 74 each having a approximately equal to, or slightly greater than, the thickness of the corresponding rail 46 at grooves 54. The distance between channels 74 is selected to be the desired spacing between rails 46 of vertical frame member 42. The width of movable connector 68 in a direction parallel to longitudinal axis 52 of vertical frame member 42 may be approximately equal to, or slightly less than, the width of each groove 54. Thus, when movable connector 68 is interlocked with rails 46 of vertical frame member 42 at grooves 54 as shown, little or no play will exist between the movable connector and the vertical frame member due to the interference fit between the movable connector and the walls 76 of the groove.

If it is desired that the width of movable connector 68 be greater than the width of grooves 54 and discretized adjustability is desired, each channel 74 of the movable connector may have regions of different widths corresponding to the thickness of corresponding rail 46 at the grooves and the thickness of that rail adjacent the grooves. If infinite adjustability is desired for horizontal frame member 40 relative to vertical frame member 42, i.e., movable connector 68 is positionable at any location along the length of the vertical frame member without regard to the locations of grooves 54 in the vertical frame member, the width of each channel 74 should be made equal to or greater than the maximum thickness of corresponding rail 46. Movable connector 68 may have an aperture 78 having threads 80 for engaging matching threads 82 of threaded rod 66. Alternatively, aperture 78 may be unthreaded. In this case a stop (not shown), e.g., a threaded nut similar to nut, may be placed outboard of movable connector 68 relative to rails 46.

Spacer 70 maintains rails 46 of horizontal frame member 40 in spaced relation from one another when nut 72 is tightened, drawing movable connector 68 toward the nut. Spacer 70 may have an aperture 84 centrally located therein for receiving threaded rod 66. However, in alternative embodiments, spacer 70 may have a non-centrally located aperture or an aperture having a U-shape, or other shape, that allows the spacer to be inserted when threaded rod 66 is already present in the space between rails 46 of standardized frame member 38. Generally, spacer 70 may be any shape and size desired. However, in connection 56, spacer 70 is shaped and sized to snugly engage grooves 54 in rails 46 of horizontal frame member 40. This limits the amount of relative movement possible between rails of horizontal frame member 40 is a direction parallel to longitudinal axis 52. If desired, spacer 70 may extend laterally to regions adjacent grooves 54, or may be sized and shaped so it does not engage the grooves at all, but rather spans over them.

Nut 72 may be any shape, size and type desired suitable for a particular application of modular support system. In the embodiment shown, nut 72 is a threaded square nut. However, nut 72 may be another shape. If nut 72 is threaded, it may be another shape, e.g., a polygonal shape other than square, such as hexagonal, or wing nut shaped, among others. Although not shown, one or more washers, such as flat washers, locking washers, and Belleville washers, among others may be used between nut and horizontal frame member.

Connection 62 shown in FIG. 4 is similar to connection of FIG. 3, but includes several features illustrative of the variety of configurations of connections possible between two standardized frame members 38, e.g., one of horizontal frame members 40 and one of vertical frame members 42. For example, FIG. 4 shows horizontal frame member 40 rotated 90° about its longitudinal axis 52 relative to the orientation of horizontal frame member 40 of FIG. 3. Accordingly, connection 62 of FIG. 4 does not require spacer 70 of FIG. 3. Rather, rails 46 of horizontal frame member 40 are maintained in spaced relation to one another by movable connector 68′, which has two spaced channels 74′, similar to movable connector 68 of FIG. 3, that each engage a corresponding one of rails 46. Similarly, rails 46 of vertical frame member 42 are maintained in spaced relation by a similar movable connector 68″ having two spaced channels 74″.

Movable connectors 68′, 68″ may be either a discretized type, i.e., is engagable with rails 46 only at grooves 54, or an infinitely positionable type, i.e., is positionable at any location along the length of the rails. In FIG. 4, movable connector 68′ is of the discretized type, and movable connector 68″ is of the infinitely positionable type. In fact, movable connector 68″ is shown engaging vertical frame member 42 at a location other than a groove 54. Connection 62 of FIG. 4 also differs from connection 56 of FIG. 3 in that neither of apertures 78′, 78″ of movable connectors 68′, 68″ is threaded. Rather, nuts 72′, 72″ threadedly engage threaded rod 66′, thereby providing the means by which connection 62 is effected. Movable connectors 68′, 68″, threaded rod 66′, and nuts 72′ may be made of any suitable material, such as the materials listed above with respect to the like members of connection 56 of FIG. 3. Also as mentioned above, one or more of threaded rod 66′ and nuts 72′ may be replaced with other types of suitable connection components.

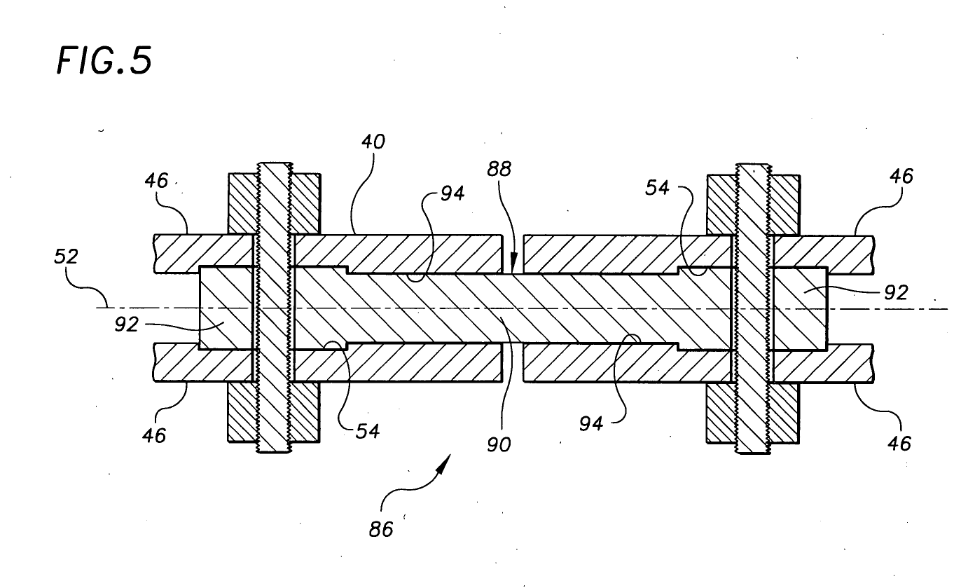

FIG. 5 shows a splice 86 connecting together the four rails 46 of the upper horizontal frame member 40. Splice 86 includes a splicing member 88 having a central portion 90 and two end portions 92. Central portion 90 may directly confront and, if desired, may contact, each rail 46 at its inner face 94. Thus, the thickness of central portion 90 may be equal to or less than the desired spacing between rails 46. Each end portion 92 may be designed to snugly engage corresponding grooves 54 in a direction parallel to the longitudinal axis 52 of horizontal frame member 40. If desired, each end portion 92 may engage each groove 54 to its full depth. However, if central portion 90 engages inner faces 94 of rails 46, thus acting as a spacer between the opposing inner faces of the rails, this need not be so. In addition, each end portion 92 may be extended to be present in the region between grooves 54 shown and the grooves (not shown) next adjacent each of the grooves shown or may be extended to engage these next-adjacent grooves or regions beyond the next-adjacent grooves. As shown, splice member 88 has a width approximately equal to the width of rails 46 in a direction perpendicular to longitudinal axis 52. However, splice member 88 may have any width desired. Splice member 88 may be made of the same material as rails 46, but may be made of any suitable material. Those skilled in the art will appreciate that splice 86 is merely illustrative of many configurations of splices possible.

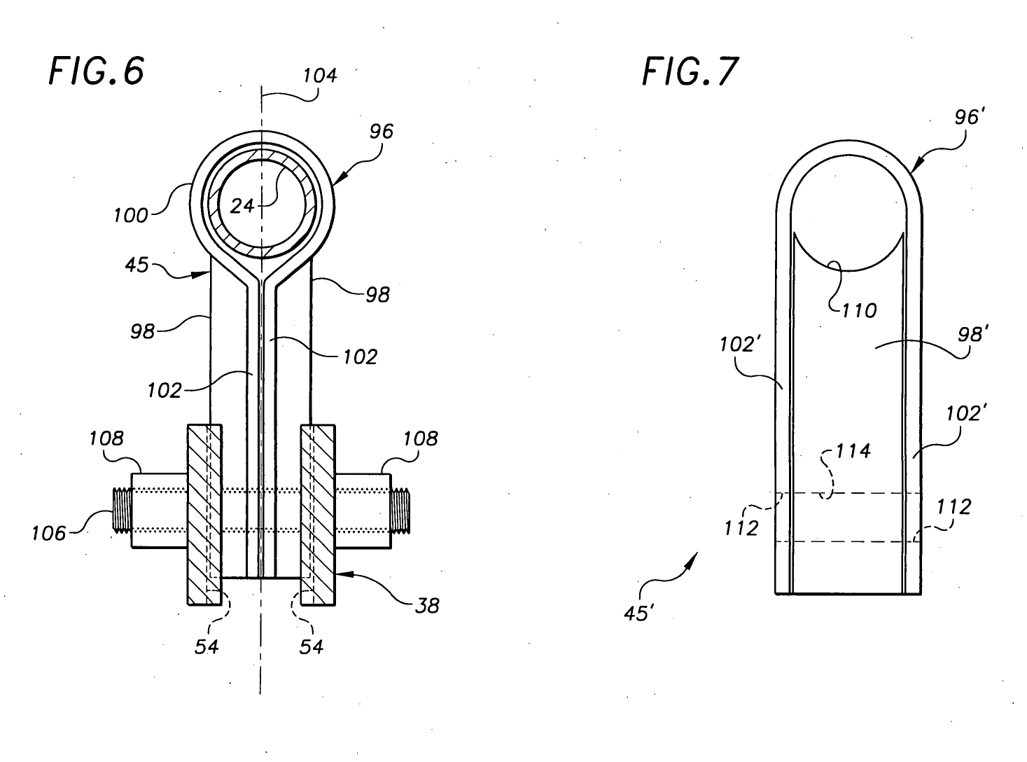

FIG. 6 shows one of supports 45 that may be used to support one of leads 24, or other supported item, supported by modular support system 20 (FIG. 1). Each support 45 may support corresponding lead 24 in spaced relation to generally planar frame 44. Accordingly, each support 45 may extend away from frame 44 in any orientation, e.g., perpendicular, with respect to the frame suitable for a particular application. Support 45 may comprise a strap 96 and a pair of spacing members 98. Strap 96 may be generally folded onto itself to form a receiving portion 100 for engaging conductor therein and a pair of legs 102 sandwiched between spacing members 98. Support 45 may be engaged with opposing grooves 54 in a corresponding pair of rails 46 of standardized frame member 38, which may be either a horizontal frame member 40 (FIG. 1) or a vertical frame member 42, depending upon the desired location of the support.

Strap 96 may be made of any suitable material. However, strap 96 is preferably made of a material that allow it to be engaged with lead 24 by separating legs 102 from one another, or “opening the strap,” a distance equal to or greater than the diameter of the lead so that the strap may be engaged with the lead in a direction substantially perpendicular to the longitudinal axis of the lead. Accordingly, strap 96 is preferably sufficiently deformable at receiving portion 100 to allow legs 102 to be opened and closed at least one time without significant damage to the strap. If strap 96 is too rigid to be installed in this manner, the strap may be engaged with lead 24 at an end of the lead in a direction substantially parallel to the longitudinal axis of the lead. In the embodiment shown, strap 96 is made of a dielectric material, such as low density cellulose pressboard to prevent it from conducting electricity carried by lead 24.

Spacing members 98 may be sized to snugly engage a pair of opposing grooves 54 in a direction parallel to longitudinal axis 52 of standardized frame member 38 and to provide the desired spacing between its pair of rails 46. Spacing members 98 may be made of any suitable material, but in the present application, should be made of a dielectric material, such as high density cellulose laminate pressboard to prevent an electrical interaction between lead 24 and the spacing members. Each spacing member 98 may be secured to a corresponding one of legs 102, e.g., by adhesive bonding or mechanical fastening, among others, or may remain unattached to the legs but held in place when properly installed in standardized frame member 38. Although legs 102 are shown as contacting one another along a central axis 104 of support 45, legs may be offset from this central axis. Accordingly, one spacing member 98 may be thicker than the other or, if legs 102 engage one of grooves 54 themselves, only one spacing member may be provided. Those skilled in the art with appreciate the many configurations of strap 96 and spacing members 98 that are possible. In addition, as shown at location 105 of FIG. 1, support may be used at a location other than between rails 46 of a corresponding standardized frame member 38.

Support 45 may be secured to one of standardized frame members 38 with any suitable connection components, such as the threaded rod 106 and threaded nuts 108 shown. Similar to the connection components used to connect horizontal frame members 40 to corresponding vertical frame members 42, threaded rod 106 and nuts 108 may be made of any material. However, when used in conjunction with transformer 22 (FIG. 2) as a part of a lead support structure, threaded rod 106 and nuts 108, or alternative connection components, should be made of a dielectric material, such as plastic, e.g., Nylon 6/6.

FIG. 7 shows an alternative support 45′ for supporting one of leads 24 (FIGS. 1 and 2), or other supported item supported by modular support system 20 of the present invention. Support 45′ is similar to support 45 of FIG. 6 in that it comprises a strap 96′ and a spacing member 98′. However, in contrast to support of FIG. 6, spacing member 98′ is positioned between the two legs 102′ of strap 45′. In addition, spacing member 98′ may be provided with a supporting surface 110 for contacting a lead captured between the spacing member and strap 96′. Supporting surface 110 may be a saddle shape conforming to the shape of a lead, or may be another shape, such as planar. Each leg 102′ of strap 96′ may contain an aperture 112 for receiving therethrough an elongate connection component, such as a threaded rod (not shown). Spacing member 98′ contains a complementary aperture 114 that, when support is connected to a standardized frame member (not shown), is in registration with apertures 112. The widths of strap 96′ and spacing member 98′ (in a direction into the sheet of FIG. 7) are each preferably substantially equal to the widths of corresponding grooves 54 of rails 46 (FIG. 1), if modular support system 20 with which support 45 is used includes such grooved rails. As described immediately below, alternative embodiments of modular support system 20 may comprise standardized frame members 38 other than parallel-rail frame members, and supports 45, 45′ may be used with these embodiments, if desired.

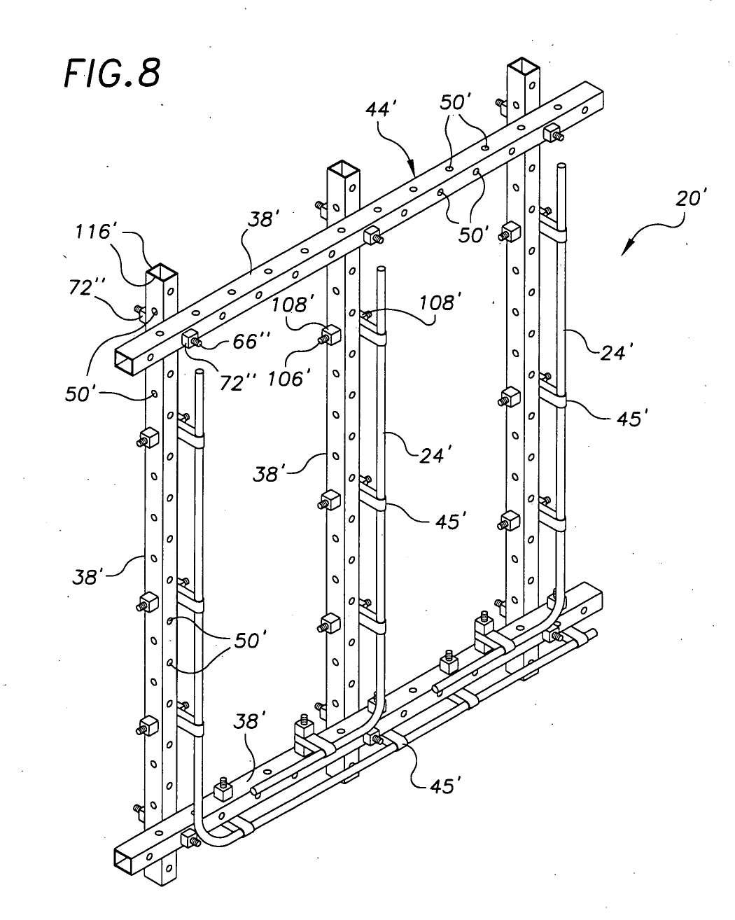

FIG. 8 shows an alternative modular support system 20′ according to the present invention. A primary difference between modular support system 20′ and modular support system 20 of FIG. 1 is that standardized frame members 38′ of the present embodiment are generally box-beam members, whereas standardized frame members 38 of FIG. 1 are parallel-rail members. As with standardized frame members 38, standardized frame members 38′ may be made of any material suitable for a particular application. In the present application, i.e., a support for supporting transformer leads, standardized frame members 38′ should be made of a dielectric material, such as a cellulose composite or plastic to prevent electrical interaction between electricity carried by leads 24′ and frame 44′. As discussed above, the cellulose composite may be a oil impregnatable laminated pressboard, or similar material.

Each standardized frame member 38′ may include a plurality of connection receivers, such as apertures 50′ along each of its longitudinal sides 116. For example, apertures 50′ may be circular apertures spaced uniformly along each longitudinal side 116 such that the apertures in each pair of opposing sides are in registration with one another but are staggered with respect to the apertures in the other pair of opposing sides. Each aperture 50′ may be sized to receive an elongate connection component, such as a threaded rod 66″ for connecting two standardized frame members 38′ to one another and a threaded rod 106′ for connecting a support, such as support 45′ of FIG. 7, to a standardized frame member.

Regular spacing of apertures 50′ along each opposing set of longitudinal sides of each standardized frame member 38′ provide for a “discretized” (rather than infinite) adjustment in two mutually orthogonal directions when the standardized frame members are assembled into grid-like configuration, as shown in FIG. 8. Thus, in the present embodiment of the invention, modular support system 20′ can be assembled using only one type of standardized frame member (frame member 38′), which can be cut to length as desired and assembled using appropriate hardware. In an alternative embodiment (not shown), two similar box-shaped structural members may be designed such that one is insertable into the other to provide the two members with a telescoping feature that provides another mode of adjustability.

The connections between standardized frame members 38 and between supports 45′ and the standardized frame members are each shown as comprising two nuts either nuts 72″ or nuts 108′ and either threaded rod 66″ or threaded rod 106′, respectively. However, similar to the connection components described above in connection with modular support system 20 of FIG. 1, the connection components of the present embodiment may be other than nuts 72″, 108′ and threaded rods 66″, 106′ and, likewise, may contain other components, such a washers. Threaded rods 66″, 106′ and nuts 72″, 108′ may be made of any suitable material. In the present case, threaded rods 66″, 106′ and nuts 72″, 108′ are made of a dielectric material, such as Nylon 6/6.

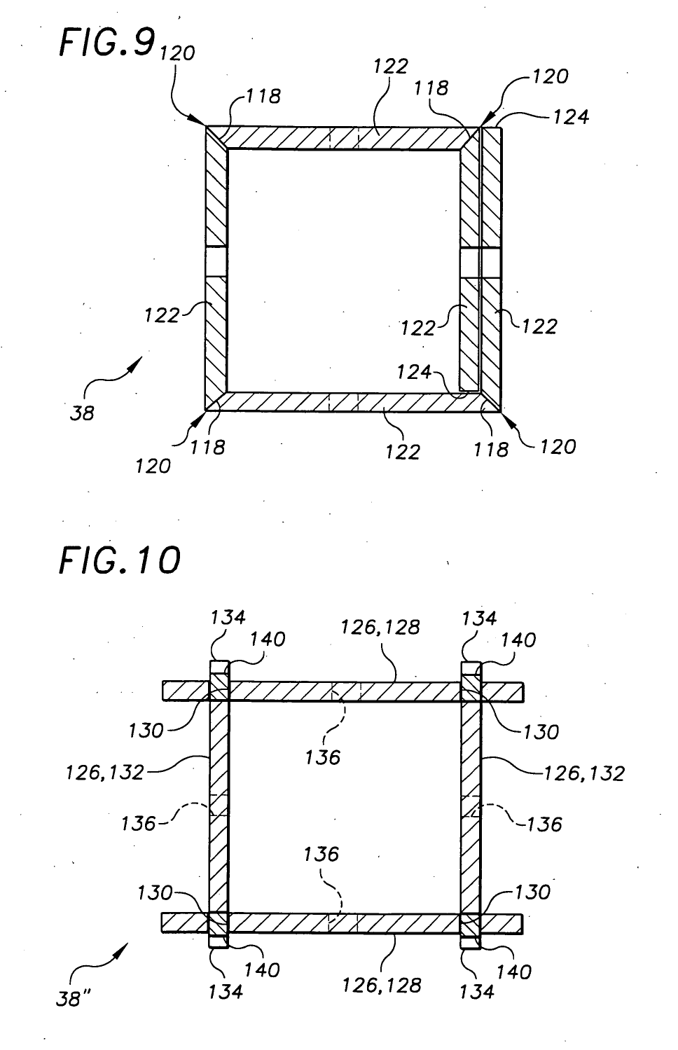

Referring to FIG. 9, each standardized frame member 38′ is generally tubular in shape. Although standardized frame member 38′ is shown as having a substantially square cross-sectional shape, it may have another polygonal cross-sectional shape, such as hexagonal, or a non-polygonal shape, such as circular. Standardized frame member 38′ may be made in any suitable manner, such as by extrusion, cold forming, assembling various components, e.g., individual sides, among others known in the art. Depending upon the material used for standardized frame members 38′, each frame member may also be made by forming V-shaped grooves in a sheet of material (not shown) and then suitably bending the remaining material at each groove, thereby forming generally mitered joints 118 at corners 120. In the illustrated standardized frame member 38′, four 90° V-shaped grooves were formed to define five side segments 122. Then, the sheet was folded at each of the grooves to form the rectangular shape shown.

Alternatively to folding the grooved sheet so that the portions adjacent longitudinal free edges 124 overlap one another, these portions may be joined to one another, e.g., by a scarf joint (not shown) along one side of the standardized frame member 38′ or by providing three V-shaped grooves (not shown) and correspondingly beveled edges that may be joined to form one of the four corners 120 of the box shape, among other joints. If a cellulose composite material is used, the depth of each of the V-shaped grooves may be equal to, e.g., about 90% of the thickness of the sheet and the sheet may be bent at each groove by first moistening the groove and then bending the sheet.

The folded sheet may be held in its finished shape using any one or more of a variety of means (not shown). For example, if the box-shape is formed by overlapping portions of the sheet, the overlapping portions may be mechanically fastened to one another, e.g., using non-conductive fasteners, and/or bonded to one another. Examples of suitable non-conductive fasteners include nuts and bolts made of a Nylon plastic, a cellulose composite or other non-conductive material. If the box shape is formed such that the longitudinal free ends of the sheet are joined at a scarf, butt or other joint, the free ends may be bonded to one another.

If desired, adhesive may be used in each mitered joint 118 to bond the faces of each V-shaped groove to one another once the sheet has been folded to the desired shape. Those skilled in the art will appreciate that other means may be used to reinforce each mitered joint 118, such as providing corner blocks or strips at the reentrant corners and suitably fastening such blocks or strips to the folded sheet.

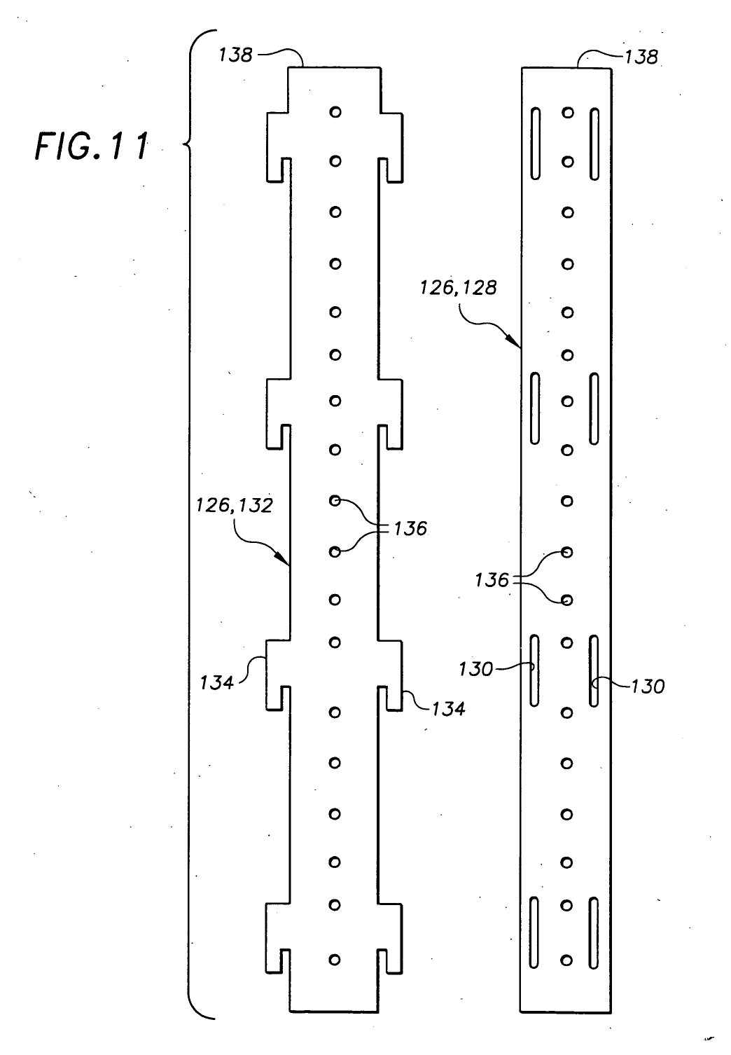

FIGS. 10 and 11 show an alternative standardized frame member 38″ that may be used in lieu of parallel rail and box beam frame members 38, 38′ of FIGS. 1 and 8, respectively. Standardized frame member 38″ may comprise four interlocking members 126 of two types, e.g., a slotted member 128 having a plurality of slots 130 and a tabbed member 132 having a plurality of hooked tabs 134, that mechanically interlock with one another via a plurality of hooked tabs 134 and corresponding slots 130. When assembled, the four interlocking members 126 generally form a box beam similar to standardized frame member 38′ of FIG. 8. Each interlocking member 126 may include a plurality of connection receivers, such as apertures 136, preferably circular, for receiving hardware for joining two or more standardized frame members 38″ to one another to form, e.g., a grid-like frame (not shown) similar to frames 44, 44′ shown in FIGS. 1 and 8. In addition, similar to standardized frame members 38′ described above, standardized frame members of the present embodiment may be made in two sizes such that one may be slidably engaged within the other to provide a telescoping feature.

Hooked tabs 134 may be offset from slots 130 so that when the tabs are fully seated into the slots, the ends 138 of slotted members 128 and tabbed members 132 are flush with one another. Hooked tabs 134 and slots 130 may be designed such that the hooked tabs frictionally engage the corresponding slotted member 128 adjacent the engaged slots to an extent that a non-trivial force is required to slide the tabbed member 132 and the corresponding slotted member relative to one another. In addition, it may be desirable to provide a stop 140 in at least one of slots 130 in the portion not occupied by a corresponding engaged hooked tab 134, or other location, to prevent interlocking members 126 from moving relative to one another. For example, each stop may comprise a wedge or a mechanical fastener, such as a screw or dowel pin.

Those skilled in the art will appreciate that although standardized frame member 38″ is shown having four interlocking members 126 forming a generally rectangular cross-sectional shape, it may be made from any number of interlocking members to form any shape desired. For example, two interlocking members (not shown) may be used to generally form a T-shape or an L-shape and three interlocking members may be used to generally form a U-shape of a Z-shape. In addition, a single uniform interlocking member (not shown) may be configured to contain both slots and hooked tabs so that only type of standardized interlocking member need be used to form various shapes in conjunction with one or more like interlocking members.

To illustrate the formation of an orthogonal grid (not shown) using, e.g., generally L-shaped frame members each composed of two interlocking members, each pair of two orthogonal frame members may be joined “back-to-back” such that the un-joined legs of the L-shape extend away from one another. These frame members may then be secured to one another with suitable fasteners. In another embodiment, one L-shaped structural member may be nested within another to provide the members with a telescoping feature. In either of these embodiments, connection receivers, e.g., apertures, may be provided for receiving connection members for securing two frame members to one another.

While the present invention has been described in connection with a preferred embodiment, it will be understood that it is not so limited. On the contrary, it is intended to cover all alternatives, modifications and equivalents as may be included within the spirit and scope of the invention as defined above and in the claims appended hereto.

1-28. (canceled)

29. A transformer, comprising:
at least a first lead; and
a lead support system, comprising:
at least one elongate frame member having a longitudinal axis; and
at least one lead support supporting said at least one lead and movably secured to said at least one elongate frame member so as to be repositionable along said longitudinal axis.

30. A transformer according to claim 29, wherein said at least one frame member includes a plurality of connection receivers spaced from one another in a direction parallel to said longitudinal axis and said at least one support is secured to said lead support system via at least one of said plurality of connection receivers.

31. A transformer according to claim 30, wherein each of said plurality of connection receivers comprises an aperture.

32. A transformer according to claim 29, wherein said at least one elongate frame member includes a first rail and a second rail extending in parallel spaced relation to one another.

33. A transformer according to claim 32, wherein each of said first and second rails includes a plurality of grooves confronting like grooves in the other of said first and second rails.

34. A transformer according to claim 33, wherein each of said first and second rails includes an aperture located at each of said grooves.

35. A transformer according to claim 29, wherein said at least one elongate frame member has a tubular cross-sectional shape.

36. A transformer according to claim 35, wherein said at least one elongate frame member includes a plurality of longitudinal faces at least some of which having a plurality of apertures disposed therealong.

37. A transformer according to claim 29, wherein said at least one elongate frame member comprises at least two elongate interlocking members interlocked with one another along their lengths.

38. A transformer according to claim 29, wherein said at least one lead support comprises a strap having receiving portion containing said at least one lead and a pair of legs extending away from said receiving portion.

39. A transformer according to claim 38, further comprises at least one spacing member located adjacent said pair of legs.

40. A transformer according to claim 39, further comprising a pair of spacing members and wherein said pair or legs is sandwiched between said pair of spacing members.

41. A transformer according to claim 39, wherein said spacing member is positioned between said pair of legs.

42. A transformer according to claim 29, wherein said at least one elongate frame member is made of cellulose pressboard.

43. A transformer according to claim 29, further comprising a plurality of elongate frame members connected to one another to form a frame, each of said plurality of elongate frame members having a length and a plurality of connection receivers spaced from one another along said length, said plurality of elongate frame members secured to one another via corresponding ones of said plurality of connection receivers.

44. A transformer according to claim 29, where each of said connection receivers comprises at least one aperture.

45-51. (canceled)

52. A method of supporting a transformer lead, comprising the steps of:
providing a frame member having a length and a plurality of connection receivers spaced from one another along said length;
selecting one of said plurality of connection receivers for receiving a connection member for securing a lead support to said frame member;
engaging said connection member with said selected one of said plurality of connection receivers; and
securing said lead support to said frame member.

53. (canceled)
